(19) United States
(12) Patent Application Publication
(10) Pub. No.: US 2015/0226808 A1
(43) Pub. Date: Aug. 13, 2015

(54) Method of Use for Electric Energy Stores, Arrangement for carrying out such a Method of Use, Battery and Motor Vehicle having such a Battery

(71) Applicants: Robert Bosch GmbH, Stuttgart (DE); Samsung SDI Co., Ltd., Yongin-si, Gyeonggi-do (KR)

(72) Inventors: Alfons Doerr, Stuttgart (DE); Christian Korn, Stuttgart (DE); Andreas Gleiter, Stuttgart (DE)

(21) Appl. No.: 14/422,957

(22) PCT Filed: Jul. 18, 2013
(86) PCT No.: PCT/EP2013/065138

§ 371 Date: Feb. 20, 2015

(30) Foreign Application Priority Data
Aug. 22, 2012 (DE) 10 2012 214 877.9

(51) Int. Cl. G01R 31/36; B60L 11/18

(52) U.S. Cl. CPC G01R 31/3648; G01R 31/3606; B60L 11/1851

(57) ABSTRACT

A method of use for an electric energy store includes defining a set of states of the electric energy store. The method further includes defining at least one separation surface which separates a first subspace of first states of the electric energy store from at least one second subspace of second states of the electric energy store and detecting at least one influencing factor from the predefinable influencing factors and determining third states of the electric energy store if the electric energy store is used. The method includes estimating at least one state by evaluating at least one influencing factor, checking whether the at least one state is in a predefined subspace for the predefined time and changing use of the electric energy store such that the at least one state is in the predefined subspace at the predefined time based on the check.

The present invention relates to a method of use for electric energy stores, an arrangement for carrying out such a method of use, a battery and a motor vehicle having such a battery which can be used, in particular, to delay the ageing of electric energy stores, in particular of lithium-ion batteries.

### PRIOR ART

In vehicles with an electric drive, the accumulators based on lithium-ion technology are being increasingly used. Owing to ageing over time owing to use, the electric storage capability and performance of these accumulators can drop significantly. Since the user of the vehicle in hybrid vehicles expects consumption of fuel, and in the case of an electric vehicle a range as well as a defined performance of his vehicle, a minimum degree of storage capability and performance are usually part of the warranty agreement for these vehicles.

On the other hand, the actual ageing of the electric store depends very greatly on a multiplicity of use parameters which can be strongly influenced both by the driver and by the vehicle operating strategy such as, for example, the driving strategy and charging strategy, temperature conditioning or the like.

Threshold values for a multiplicity of histograms which cannot be overwritten owing to use are conventionally agreed between the manufacturer of storage systems and vehicle manufacturers. The most important critical influencing factors for ageing are represented in the individual histograms. Compliance with the threshold values is usually tracked in the battery control device.

A significant disadvantage when using histograms for warranty agreements is that the interaction between the individual influencing factors cannot be taken into account. This means that one influence to which a battery system is excessively exposed cannot be compensated by avoiding another influence. To do this, the individual threshold values in the histograms would have to be dynamically adapted in accordance with the degree to which the other histograms were filled up. Introducing such rules is very complicated and is not sufficiently transparent in the context of a warranty agreement.

### DISCLOSURE OF THE INVENTION

A particular advantage of the invention is that the storage capability and performance of electric energy stores can be maintained over a relatively long time period. This is achieved, in particular, in that the electric energy store satisfies the warranty conditions over the entire warranty time period. According to the invention there is therefore provision for a set of states which the electric energy store can assume to be defined. The states can be defined, for example, in that parameters are considered which influence the state of the electric energy store, in particular its ageing and specifically the storage capability or performance of the electric energy store. Influencing factors such as, for example, a temperature characteristic Tₙ, a parking characteristic Pₙ, a driving characteristic Dₙ or the like can be formed from these parameters. The influencing factors are preferably defined as functions of parameters such as the temperature T, charge throughput ΔQ or the like. These influencing factors span the space of the states of the electric energy store, that is to say the states, whose components are formed by the influencing factors, can be represented as points in this space. In particular, the states describe the ageing of one or more electric energy stores. In one preferred embodiment there is provision that all or some of the states which can only be exited irreversibly, and therefore define a time sequence, are detected.

In one preferred embodiment there is provision that the states are produced by evaluating use profiles for the electric energy store. In this context, for example, the functions of the influencing factors are evaluated at discrete points tᵢ. In a further preferred embodiment there is provision that the states are evaluated to determine whether or not a state satisfies warranty requirements. Depending on the result of the evaluation, a state is marked, for example with +1 or −1. The states are therefore assigned to two classes which are characterized by the marking +1 or −1. A preferred embodiment provides that the states of the electric energy store are calculated on the basis of an ageing model of the electric energy store. In one preferred embodiment, there is provision that the states which are calculated in this way are supplemented and/or corrected by states which are determined in field trials. The states determined in field trials may replace or supplement states which have been determined on a model basis.

The invention also provides for the marked states in the space to be separated from one another by a separation surface, with the result that two subspaces are produced, a first subspace of which contains only states which satisfy the warranty requirements, and a second subspace of which contains only states which do not satisfy the warranty requirements. In relatively high-dimension state spaces the separation surface is a hypersurface. In one preferred embodiment, there is provision that the separation surface (also referred to as an envelope surface or envelope curve), is determined using the method of support vectors (support vector machine). Such marked state spaces can be produced individually for an entire class of electric energy stores or for each electric energy store. The state spaces in which states are marked are also referred to as classification spaces.

The definition of the envelope curve is preferably carried out as offline training.

After the one envelope curve is defined, the states assumed by the at least one electric energy store are determined during the operation of the at least one electric energy store and it is checked whether the strategy for operating the at least one electric energy store has to be changed. This phase of determining states and applying the operating strategy will be described in more detail below.

If an electric energy store is used, preferably from the start of the use, the influencing factors which occur during the use are determined, for example in that the functions of the temperature characteristic Tₙ, parking characteristic Pₙ, driving characteristic Dₙ or the like are calculated. Using the influencing factors, the associated states which the electric energy store assumes during the use are determined and at least some of the assumed states are entered into the classification space as a trajectory. If the set of assumed states is large enough, states are estimated which are expected to be assumed by the electric energy store. For this purpose, at least some of the assumed states, preferably all the assumed states which have been assumed during a first time period are preferably evaluated. The first time period can be, for example, approximately a year. In one preferred embodiment there is provision that the estimation comprises the determination of at least one state at at least a first predefined (future) time. The first predefined time is preferably the end of the warranty period. One preferred embodiment provides that a profile of the use of the electric energy store (use profile) is determined from the states assumed in the first time period. The state of the electric energy store at the first predefined time is estimated on the condition that the determined use profile is retained. The estimation is preferably an extrapolation.

The invention also provides checking whether or not the future state satisfies the warranty requirements at the first predefined time. Since the states which have been assumed during the first time period, but at least the state at the start of the use of the electric energy store, satisfy the warranty requirements, in one preferred embodiment the checking comprises determining whether the state at the first predefined time and at least some of the states assumed during the first time period, in particular the state at the start of the use, occur in the same subspace. If the state at the first predefined time and at least some of the states assumed during the first time period occur in the same subspace, the state assumed at the first predefined time also satisfies the warranty requirements. If the state for the first predefined time and at least some of the detected states detected for the first time period are separated by the separation plane, the state assumed at the first predefined time does not satisfy the warranty requirements.

Depending on the result of the check, the use, in particular the operating strategy, of the electric energy store is changed. In particular, the use is changed when the check reveals that the state for the first predefined time (lying in the future) does not satisfy the warranty requirements. Otherwise, the previous use strategy is retained. The operating strategy is therefore selected in such a way that the state at the first predefined time lying in the future is still in the “good” subspace of the feature space.

The change comprises, in particular, changing the use to the effect that the state for the first predefined time satisfies the warranty requirements if the electric energy store is operated with the changed use.

A preferred embodiment provides that at a second predefined time, in particular at the end of the first time period, at least one future state, in particular at least one state at the at least one first predefined time, is estimated, wherein the estimation is based on the changed use. This estimation reveals a new trajectory which describes the states which are assumed if the electric energy store is operated with the changed use. The use on which the estimation is based is changed until the state for the first predefined time satisfies the warranty requirements. In one preferred embodiment there is provision that at predefined time intervals after the second time at least some of the states assumed in the past are evaluated in order to determine the state for the first predefined time and to check whether or not the state determined in the new estimation satisfies the warranty requirements. Depending on the result of the check, the use of the electric energy store is, if appropriate, changed again.

In one preferred embodiment there is provision that the change comprises a change in the cooling and/or a change in the charging process compared to the cooling described by the initial use profile and/or the charging process described by the initial use profile. Alternatively, or in parallel with this, the change of the use can be brought about in that hardware instructions to a user of the electric energy store are output via a visual or acoustic interface, or generally via a man/machine interface.

In another preferred embodiment there is provision that in the training phase the states are divided into more than two classes. If the number of classes is N, up to (N−1)*N/2 separation surfaces are defined.

In this specific embodiment it is checked whether the state for the predefined time lying in the future is separated by one or more separation surfaces from at least some of the states determined during the use, that is to say whether or not the state for the predefined time occurs in a predefined subspace (target subspace). Depending on the result of this check, the use of the electric energy store is changed in such a way that the state which is assumed in the case of changed use at the predefined time occurs in the predefined target subspace.

In one preferred embodiment there is provision that step-wise checking occurs in the sense that states are approximated for a plurality of predefined times. Checking then occurs as to whether the approximated state at the predefined times occurs in a predefined target subspace. If one of the approximated states does not occur in the predefined target subspace, the use strategy of the at least one electric energy store is changed in such a way that the states assumed in the case of changed use at the predefined times occur in the predefined target subspace.

An arrangement according to the invention has at least one data processing unit, such as for example a processor, an electronic module or a chip and is configured in such a way that a method for using an electric energy store can be carried out, wherein the method comprises the following steps:
defining a set of states of the electric energy store, wherein the states are described by predefinable influencing factors,
defining at least one separation surface which separates a subspace of first states of the electric energy store from at least one subspace of second or further states of the electric energy store,
in the case of use of the electric energy store, detecting at least some of the influencing factors and determining states of the electric energy store which are assumed in the case of use,
estimating at least one state, assumed in the case of future use of the electric energy store at at least one predefined time, by evaluating at least some of the detected influencing factors,
checking whether the at least one state is in a predefined subspace for the at least one predefined time, and
depending on the result of the check, changing use of the electric energy store in such a way that the at least one state which is assumed in the case of changed use is in at least one predefined subspace at the at least one predefined time.

In one preferred embodiment there is provision that the arrangement is implemented as part of a battery control device and/or of a vehicle control device.

A further aspect of the invention relates to a battery which can be combined with an arrangement, wherein the arrangement has at least one data processing unit and wherein the arrangement is configured in such a way that a method for using an electric energy store can be carried out, wherein the method comprises at least the following steps:
defining a set of states of the electric energy store, wherein the states are described by predefinable influencing factors,
defining at least one separation surface which separates a subspace of first states of the electric energy store from at least one subspace of second or further states of the electric energy store,
in the case of use of the electric energy store, detecting at least some of the influencing factors and determining states of the electric energy store which are assumed in the case of use,
estimating at least one state, assumed in the case of future use of the electric energy store at at least one predefined time, by evaluating at least some of the detected influencing factors,
checking whether the at least one state is in a predefined subspace for the at least one predefined time, and
depending on the result of the check, changing use of the electric energy store in such a way that the at least one state which is assumed in the case of changed use is in at least one predefined subspace at the at least one predefined time.

The battery is preferably a lithium-ion battery or the battery comprises electro-chemical cells which are embodied as lithium-ion battery cells. In this context, a plurality of lithium-ion battery cells can be combined to form one electro-chemical module in each case. The invention is not limited here to lithium-ion batteries but rather relates to all electric energy stores which are subject to ageing over time and/or owing to use, which ageing becomes perceptible within the usually recommended period of use. In particular, the electric energy store can also be a lithium-air battery.

Another aspect of the invention relates to a motor vehicle having an electric drive motor for driving the motor vehicle and a battery which is connected or can be connected to the electric drive motor according to the aspect of the invention described in the preceding paragraph. However, the battery is not restricted to such a purpose of use but rather can also be used in other electric systems.

The invention defines a common threshold value for all the significant influencing factors in the form of an envelope curve in a multi-dimensional space, wherein the multi-dimensional space is spanned by the functions of the specified influencing factors. The individual profile of use is mapped in this space in the form of a trajectory.

Furthermore, the invention provides a method which influences the use of a battery system early in such a way that the common threshold value of all the influencing factors is not exceeded over the entire warranty period.

The invention can be summarized as follows:

The use of a suitable n-dimensional classification method for the detection and definition of warranty agreements forms a significant aspect. For this, in one preferred embodiment the method of support vectors (support vector machine) is used, which is integrated, for example, into a vehicle control device for the classification and tracking of the use and the adaptation of the operating strategy.

A further important aspect is the selection of the functions which span the classification space. In one preferred embodiment, the minimum set of functions (Tₙ, Pₙ, Dₙ) is formed here by the following sums:

$$〈 {T}_{n} 〉 = \frac{1}{n} {\sum }_{i = λ , … , n} {T}_{i} , \\ 〈 {P}_{n} 〉 = {\sum }_{i = λ , … , n} AF ( {SOC}_{i} ) \cdot Δ {t}_{i} and$$

$$〈 {D}_{n} 〉 = {\sum }_{i = 1 , … , n} AF ( Δ {SOC}_{i} ) \cdot Δ {Q}_{i} .$$

The functions can be referred to as a temperature characteristic Tₙ, parking characteristic Pₙ and driving characteristic Dₙ, where Tᵢ describes the temperature at the time t=i, Δtᵢ defines a time period or time step, ΔQᵢ denotes the charge throughput and the variables AF(SOCᵢ) and AF(ΔSOCᵢ) denote stress factors which depend on the state of charge SOCᵢ of the electric energy store or of the change in the state of charge ΔSOCᵢ at the time tᵢ.

Another significant aspect of the invention is a method for determining whether or not the battery system will satisfy the warranty requirements on the basis of a current use profile when this use profile is continued.

A further significant aspect of the invention comprises a method in which the warranty requirements can be satisfied by adapting a use profile, by changing an operating strategy and/or by means of specific requirements made of a user.

Advantageous developments of the invention are specified in the dependent claims and described in the description.

### DRAWINGS

Exemplary embodiments of the invention are explained in more detail on the basis of the drawings and the following description. In the drawings:

FIG. 1 shows an illustration of an exemplary classification space with a separation surface and a trajectory describing the battery states, when an initial operating strategy is retained, and

FIG. 2 shows an illustration of an exemplary classification space with a separation surface and a trajectory, describing the battery states, with a changed initial operating strategy.

### EMBODIMENTS OF THE INVENTION

Firstly, an exemplary n-dimensional classification method for detecting and defining the warranty agreement will be described with reference to an

### Exemplary Embodiment of the Invention

a) Motor vehicle manufacturers conventionally make available typical use profiles. Functions, such as for example the abovementioned functions Tₙ, Pₙ and Dₙ, are calculated discretely for these use profiles as a function of time steps tᵢ and the energy throughput ΔQᵢ. The stress factors AF(SOCᵢ) and AF(ΔSOCᵢ) (AF=accelerating factor) are determined in corresponding test methods. In one exemplary embodiment, the stress factors are stored as characteristic diagrams, for example in storage means of the battery control device or of the vehicle control device. If a battery system satisfies the warranty requirements at the use step n corresponding to the current ageing modeling of the battery system, the use step is marked with the label +1. If a use step no longer satisfies the warranty requirements, this use step and the (chronologically) following use steps are marked with the label −1. In one preferred embodiment, the use profiles which are made available are additionally varied further in relation to further possible operating states, with the result that all or at least all of the decisive possible operating states in the classification space are provided with a label and a suitable separation surface 100 can be determined by using the support vector machine. In specific cases, the separation surface 100 can be a separation plane. In particular operating states in the surroundings of the boundary between operating states which satisfy the warranty requirements and operating states which do not satisfy the warranty requirements are considered to be decisive operating states.

In a subsequent step, in field trials states are additionally detected and, as described above, are marked with the label +1 or −1 in accordance with the satisfaction of the warranty requirements. If a state which has been evaluated using the ageing model and which contradicts the findings from the field is located in the direct vicinity of a state which is determined from the field trials, the label which is estimated with the model is deleted. In one exemplary embodiment, the separation surface 100 is continuously adapted using the concept of the support vector machine.

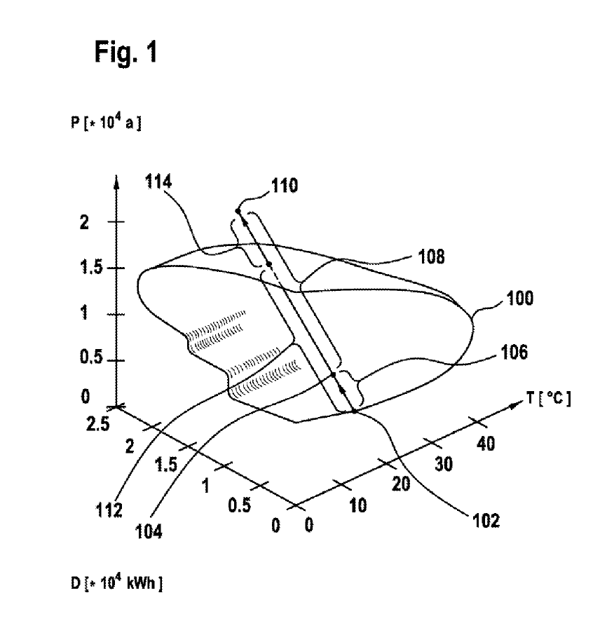

As a result, the classification space contains as a subset a separation surface 100, wherein the separation surface 100 separates the battery states which satisfy the warranty requirements from the battery states which do not satisfy the warranty requirements (cf. FIG. 1). During the use of the battery system, the battery states are detected and recorded. The battery states are mapped into the classification space from the start of the use 102 of the battery system. At a predefined time 104 during the use, the expected future battery states are estimated, for example by extrapolation, from the preceding battery states. As a result, a trajectory is obtained in the classification space. The trajectory is composed of a first part, which describes the detected operating states 106, and a second part, which describes the coming battery states 108 which are assumed if the initial use parameters which constitute the basis of the estimation are retained. In specific cases the trajectory may be a vector. The estimation is calculated up to the end 110 of the warranty period or up to the end of the warranty kilometerage or mileage. Typical units for the end of the warranty period are, for example, ten years or approximately 160.00 km (100,000 miles). The trajectory (vector) can also be divided into a first region 112 within the envelope curve 100 which describes the operating states which satisfy the warranty requirements, and a second region 112 which describes the battery states which no longer satisfy the warranty requirements. In the case of the use illustrated in FIG. 1, the warranty requirements would not be satisfied at the end 110 of the warranty period.

b) Depending on the design of the overall system, as a rule further influencing factors occur which are significant for retaining the warranty agreement. Accordingly, additional dimensions with functions of the corresponding influencing factors can be added to the classification space or the existing functions can be extended with respect to the influencing factors, such as for example as follows:

$$〈 {\tilde{P}}_{n} 〉 = {\sum }_{i = 1 , … , n}^{ } AF ( {SOC}_{i} ) \cdot AF ( {X}_{i} ) \cdot AF ( {Y}_{i} ) \cdot Δ {t}_{i} ,$$

where AF(Xᵢ) and AF(Yᵢ) describe the stress factors which depend on the influencing factors Xᵢ and Yᵢ.
c) If the separation surface 100 is produced and validated, the current use is entered in the classification space as a trajectory during the operation of the battery system. The use of the starting point (start of the use 102) up to a given use time 104 can be represented by a trajectory, for example a vector, in the classification space. This part of the trajectory forms the first part which describes the detected operating states 106. In order to generate the second part of the trajectory, an expected use for the future is estimated, for example extrapolated, from use data which have been detected within a predefinable time period (for example within a year) starting from the first use. Under the premise that the use behavior is retained the state of the battery at the end 110 of the agreed use is estimated by corresponding lengthening of the first part of the trajectory. The end 110 of the agreed use can be predefined, for example, by a time period of use and/or a kilometerage or mileage.

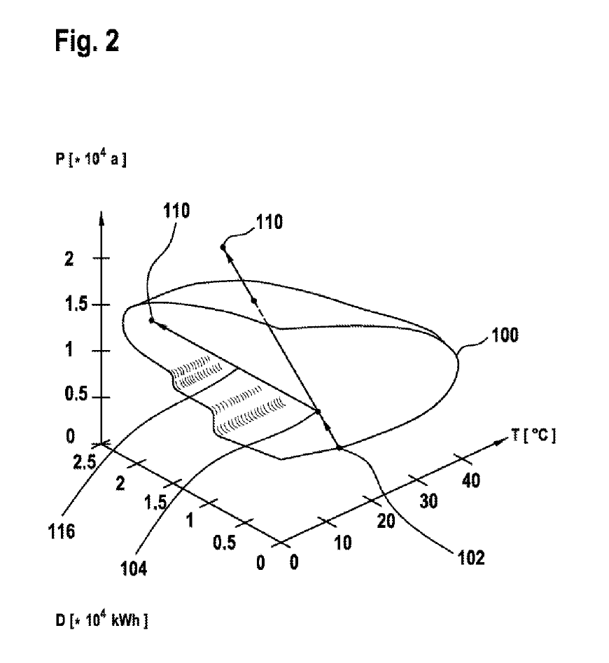

In order to be able to satisfy the warranty agreement at the end 110 of the use, it may be necessary for the initial operating strategy to be adapted if the estimation reveals that retaining the initial operating strategy would lead to infringement of the warranty agreement. The adaptation is performed in such a way that the adapted trajectory 116 of the estimation always lies within the envelope curve (separation surface 100) up to the end 110 of the agreed use period (cf. FIG. 2).

In one preferred embodiment, the operating strategy is influenced by an adapted cooling concept for adaptation. The influencing preferably occurs automatically. Alternatively or additionally to the preferred automatic adaptation of the cooling concept, the operating strategy can also be influenced indirectly, for example by feedback functions to the user.

The invention is not restricted in its embodiment to the preferred exemplary embodiments specified above. Instead, a number of variants are conceivable which make use of the method according to the invention, the arrangement according to the invention, the battery according to the invention and the motor vehicle according to the invention, even in the case of embodiments which are basically of a different type.

1. A method of use for electric energy store, comprising:
defining a set of states of the electric energy store, wherein the states are described by predefinable influencing factors;
defining at least one separation surface, wherein the at least one separation surface separates a first subspace of first states of the electric energy store from at least one second subspace of second states of the electric energy store, wherein the first states and second states are a first subset of the set of states;
detecting at least one influencing factor from the predefinable influencing factors and determining third states of the electric energy store, wherein the third states are assumed if the electric energy store is used;
estimating at least one state by evaluating the at least one influencing factor, wherein the at least one state is assumed if the electric energy store is used at one predefined time in future;
checking whether the at least one state is in a predefined subspace for the predefined time, wherein the predefined subspace is a second subset of at least one of the first subspace and the second subspace; and
changing use of the electric energy store such a way such that the at least one state is in the predefined subspace at the predefined time based on the check.

2. The method as claimed in claim 1, further comprising:
at least one of (i) checking whether the at least one state is separated from at least one of the third states by the at least one separation surface for the predefined time and (ii) changing the use of the electric energy store such that the third states and the at least one state are in the same subspace at the predefined time based on the check whether the at least one state is in the predefined subspace for the predefined time.

3. The method as claimed in claim 1, further comprising:
producing a use profile from at least one of the detected third states.

4. The method as claimed in claim 1, wherein the change of use of the electric energy store comprises a change in an operating strategy.

5. The method as claimed in claim 1, wherein the change of use of the electric energy store comprises at least one of:
(i) at least one of a change in a cooling and a change in a charging process compared to the cooling described by a use profile and
(ii) the charging process described by the use profile.

6. The method as claimed in claim 1, further comprising:
providing information for a changed use of the electric energy store using a man/machine interface.

7. The method as claimed in claim 1, wherein the detected third states are represented as a trajectory in the first or second subspace of the set of states of the electric energy store, and the at least one state is estimated for the predefined time by extrapolation of the trajectory.

8. An arrangement comprising:
at least one data processing unit,
wherein the arrangement is configured to perform a method of use for an electric energy store, and
wherein the method includes:
defining a set of states of the electric energy store, wherein the states are described by predefinable influencing factors;
defining at least one separation surface, wherein the at least one separation surface separates a first subspace of first states of the electric energy store from at least one second subspace of second states of the electric energy store, wherein the first states and second states are a first subset of the set of states;
detecting at least one influencing factor from the predefinable influencing factors and determining third states of the electric energy store, wherein the third states are assumed if the electric energy store is used
estimating at least one state by evaluating the at least one influencing factor, wherein the at least one state is assumed if the electric energy store is used at one predefined time in future;
checking whether the at least one state is in a predefined subspace for the predefined time, wherein the predefined subspace is a second subset of at least one of the first subspace and the second subspace; and
changing use of the electric energy store such that the at least one state is in the predefined subspace at the predefined time based on the check.

9. The arrangement as claimed in claim 8, wherein the arrangement is combined with a battery.

10. A motor vehicle comprising:
an electric drive motor configured to drive the motor vehicle; and
a battery configured to be connected to the electric drive motor and combined with an arrangement,
wherein the arrangement includes at least one data processing unit and the arrangement is configured to perform a method of use for an electric energy store, and
wherein the method includes:
defining a set of states of the electric energy store, wherein the states are described by predefinable influencing factors;
defining at least one separation surface, wherein the at least one separation surface separates a first subspace of first states of the electric energy store from at least one second subspace of second states of the electric energy store, wherein the first states and second states are a first subset of the set of states;
detecting at least one influencing factor from the predefinable influencing factors and determining third states of the electric energy store, wherein the third states are assumed if the electric energy store is used
estimating at least one state by evaluating the at least one influencing factor, wherein the at least one state is assumed if the electric energy store is used at one predefined time in future;
checking whether the at least one state is in a predefined subspace for the predefined time, wherein the predefined subspace is a second subset of at least one of the first subspace and the second subspace; and
changing use of the electric energy store such that the at least one state is in the predefined subspace at the predefined time based on the check.
